(19) United States
(12) Patent Application Publication
(10) Pub. No.: US 2018/0119273 A1
(43) Pub. Date: May 3, 2018

(54) EVAPORATION APPARATUS AND METHOD OF EVAPORATION USING THE SAME

(71) Applicant: Industrial Technology Research Institute, Hsinchu (TW)

(72) Inventors: Chih-Yung Huang, Taichung City (TW); Shih-Chin Lin, New Taipei City (TW); Ching-Chiun Wang, Miaoli County (TW)

(73) Assignee: Industrial Technology Research Institute, Hsinchu (TW)

(21) Appl. No.: 15/384,333

(22) Filed: Dec. 20, 2016

(30) Foreign Application Priority Data
Oct. 28, 2016 (TW) 105135049

(51) Int. Cl. C23C 14/50; C23C 14/24

(52) U.S. Cl. CPC C23C 14/505; C23C 14/243

(57) ABSTRACT

The disclosure is an evaporation apparatus and a method of evaporation using the same. The evaporation apparatus includes an evaporation chamber, an evaporation source, a carrying device, and a fluid disturbance device. The evaporation chamber has an evaporation space, the evaporation source is disposed at a lower part in the evaporation space, and the evaporation source is suitable for accommodating an evaporation source material. The carrying device is disposed to be rotatable about a reference axis as the center at an upper part in the evaporation space and is opposite to the evaporation source; the carrying device is suitable for carrying a substrate and positions the substrate between the evaporation source and the carrying device. The fluid disturbance device is suitable for injecting a disturbed fluid towards the carrying device in the evaporation space.

### CROSS-REFERENCE TO RELATED APPLICATION

This application claims the priority benefits of Taiwan application serial no. 105135049, filed on Oct. 28, 2016. The entirety of the above-mentioned patent application is hereby incorporated by reference herein and made a part of this specification.

### TECHNICAL FIELD

The disclosure relates an evaporation apparatus and a method of evaporation using the same, and more particularly relates to an evaporation apparatus having a fluid disturbance device and a method of evaporation.

### BACKGROUND

The evaporation process is a widely used thin film deposition technique. An existing evaporation apparatus includes an evaporation chamber, a carrying device disposed in the evaporation chamber, and an evaporation source opposite to the carrying device. The evaporation source carries an evaporation material. When performing the evaporation process, the evaporation material is evaporated or sublimed by way of heating and fills in the evaporation chamber in the form of evaporation particles. At the same time, when an object awaiting deposition, such as a substrate waiting for evaporation is furnished on the carrying device, the evaporation particles filling the evaporation chamber accumulate on the surface of the substrate to form an evaporation film thereafter.

The thickness of the evaporation film can be determined by adjusting various parameters of the evaporation process, such as evaporation time, distance between the substrate and the evaporation source, temperature to which the evaporation source is heated, etc. However, when the thickness of the evaporation film to be obtained is relatively thin (such as forming an atomic layer), an issue of poor compactness of the deposition film is still easily present.

### SUMMARY

The disclosure uses a fluid disturbance device to inject a disturbed fluid towards an object awaiting deposition, such as a substrate in the evaporation space. The fluid disturbance device is disposed in an evaporation apparatus and includes a plurality of nozzles injecting the disturbed fluid; the plurality of nozzles are inclined at an angle, guiding the particles of the evaporation film material to move towards a carrying device.

According to an aspect of the disclosure, an evaporation apparatus is provided, including an evaporation chamber, an evaporation source, a carrying device, and a fluid disturbance device. The evaporation chamber has an evaporation space. The evaporation source is disposed at a lower part in the evaporation space, and the evaporation source is suitable for accommodating an evaporation source material. The carrying device is disposed to be rotatable about a reference axis as the center at an upper part in the evaporation space and is opposite to the evaporation source. The carrying device is suitable for carrying a substrate and positioning the substrate between the evaporation source and the carrying device. The fluid disturbance device is suitable for injecting a disturbed fluid towards the carrying device in the evaporation space.

According to the disclosure, an evaporation method is provided, including using an evaporation apparatus in which an evaporation source is disposed in an evaporation space of an evaporation chamber, and located at a lower part in the evaporation space, and the evaporation source is suitable for accommodating an evaporation source material; disposing a carrying device to be rotatable about a reference axis as the center at an upper part in the evaporation space, and opposite to the evaporation source, wherein the carrying device is suitable for carrying an object awaiting deposition, such as a substrate and positioning the substrate between the evaporation source and the carrying device; and disposing a fluid disturbance device, suitable for injecting a disturbed fluid towards the carrying device in the evaporation space; wherein the fluid disturbance device includes a plurality of nozzles, the plurality of nozzles being disposed in symmetrical arrangement with the reference axis as the center, and each of the plurality of nozzles being disposed to inject the disturbed fluid in an injecting direction, the injecting direction intersecting with the reference axis at an angle, such that the disturbed fluid travels towards the periphery of the carrying device.

To make the disclosure more comprehensible, embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a schematic diagram of an evaporation apparatus according to an embodiment of the disclosure.

FIG. 2 illustrates a side-view schematic diagram of an evaporation apparatus according to an embodiment of the disclosure.

FIG. 3A to FIG. 3D illustrate schematic diagrams of a nozzle of embodiments.

FIG. 4A to FIG. 4D illustrate schematic diagrams of a nozzle of another embodiment.

### DETAILED DESCRIPTION OF DISCLOSED EMBODIMENTS

The following paragraphs provide embodiments as detailed descriptions. The embodiments only serve as exemplary descriptions, and should not be construed as limitations to the scope that the disclosure intends to cover.

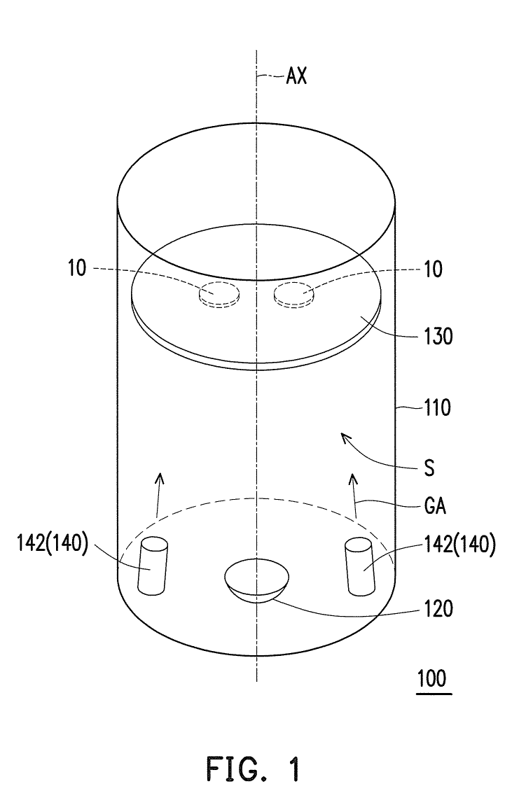

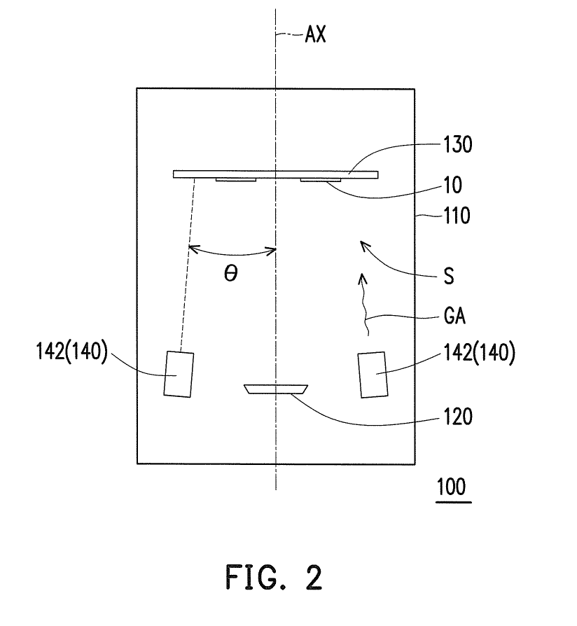

Please refer to FIG. 1 illustrating an evaporation apparatus according to an embodiment of the disclosure. The disclosure discloses an evaporation apparatus 100, as shown in the perspective view of FIG. 1 and the side-view schematic diagram of FIG. 2, including an evaporation chamber 110, an evaporation source 120, a carrying device 130, and a fluid disturbance device 140. The evaporation chamber 110 defines an evaporation space S. The evaporation source 120 is disposed at one end of the evaporation chamber 110, namely at a lower part in the evaporation space S, and the carrying device 130 and the evaporation source 120 are oppositely disposed. The carrying device 130 is at an upper part in the evaporation space S for carrying an object awaiting deposition, such as a substrate 10. The substrate 10 is placed on the carrying device 130 and faces the evaporation source 120. The fluid disturbance device 140 injects a disturbed fluid GA towards the evaporation space S and causes the disturbed fluid GA to travel towards the periphery of the carrying device 130.

Generally, the carrying device 130 is loaded with one or a plurality of substrates 10, and positions the substrate 10 between the evaporation source 120 and the carrying device 130. The carrying device 130 is suitable for rotating about a reference axis AX as the axial center, causing the substrate 10 to be moved along an annular path surrounding the reference axis AX. At the same time, the reference axis AX can pass through the disposed position of the evaporation source 120, or the disposed position of the evaporation source 120 can also be changed according to different needs. In an embodiment, the evaporation source 120 includes a crucible. The crucible has an opening in a direction towards the carrying device for accommodating an evaporation source material. The evaporation source also includes a heating portion for heating the evaporation source material. The evaporation source material sublimes or evaporates into evaporation particles (for example, in a gaseous state), and the evaporation particles move away from the evaporation source 120 and towards the carrying device 130 to reach a surface of the substrate 10. At this time, rotation of the carrying device 130 causes the substrate 10 to be moved in the annular path surrounding the reference axis AX, facilitating the substrate 10 to be in contact with the evaporation particles at different locations.

More specifically, the fluid disturbance device 140 injects the disturbed fluid GA towards the evaporation space S and causes the fluid GA to travel towards the periphery of the carrying device 130, such that the evaporation particles travel towards the carrying device 130 in a direction so as to be concentrated with the reference axis AX as the center, namely to travel towards the substrate 10. In addition, when the fluid disturbance device 140 injects the disturbed fluid GA towards the evaporation space S, and the fluid GA travels towards the carrying device 130, the fluid GA and the evaporation particles come into contact with each other, thereby increasing kinetic energy and momentum of the evaporation particles.

The following paragraphs further coordinated with the drawings provide description of the configuration of the fluid disturbance device 140 and embodiments thereof.

First of all, as shown in FIG. 1 and FIG. 2, the reference axis AX passes through where the evaporation source 120 is positioned. The fluid disturbance device 140 includes a plurality of nozzles 142. The plurality of nozzles 142 are disposed in point symmetry with the reference axis AX as the center. At the same time, the disposed position of the evaporation source 120 is at the middle point between the two nozzles 142. In other words, respective distances from the two nozzles 142 to the evaporation source 120 are the same. When the quantity of the nozzles 142 is greater than two, the disposed position of the evaporation source 120 is at the geometric center point of a geometric shape defined by the disposition locations of the plurality of nozzles 142. Distances from the plurality of nozzles 142 to the evaporation source 120 are the same, and distances between adjacent two of the plurality of nozzles 142 are also the same.

Each of the nozzles 142 is disposed to inject the disturbed fluid GA in an injecting direction. Each of the injecting directions intersects with the reference axis AX at an angle θ, such that the disturbed fluid GA from each of the nozzles 142 mainly travels towards the periphery of the carrying device 130. In an embodiment, the angle θ is defined by an angle of inclination of each of the nozzles 142. Since the design of size and shape of the evaporation chamber 110 and the relative distance between each of the members can be adjusted according to different needs for process, the angle of inclination of the nozzles 142 can be adjusted according to the injecting directions as needed. At the same time, the angle θ can also be changed according to different needs. In this embodiment, the angle θ is between 0° to 15° and not equal to 0°.

When the substrate 10 is disposed on the carrying device 130, the angle of inclination of each of the nozzles 142 (namely, each of the injecting directions, or namely, a travelling direction of the disturbed fluid GA from each of the nozzles 142) can travel targeting the substrate 10. As needed for the process, when a plurality of rows of the substrate 10 are sequentially placed on the carrying device 130 from the center of the carrying device 130 outwards, the angle of inclination of each of the nozzles 142 (namely, each of the injecting directions, or namely, a travelling direction of each of the disturbed fluid GA from each of the nozzles 142) travels targeting the substrate 10 at the outermost region. During the process of evaporation, the disturbed fluid GA forms a gaseous barrier surrounding the periphery of the region disposed with the substrate 10, such that the evaporation particles inside the gaseous barrier travel towards the carrying device 130 in a direction to be concentrated with the reference axis AX as the center, namely to travel towards the substrate 10, and the evaporation particles obtain higher kinetic energy and momentum. Thus, the evaporation particles reaching the surface of the substrate 10 form an evaporation film with higher compactness.

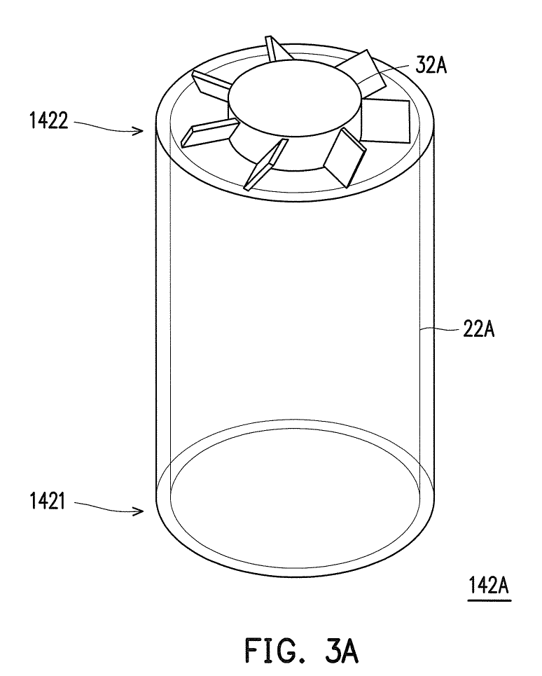

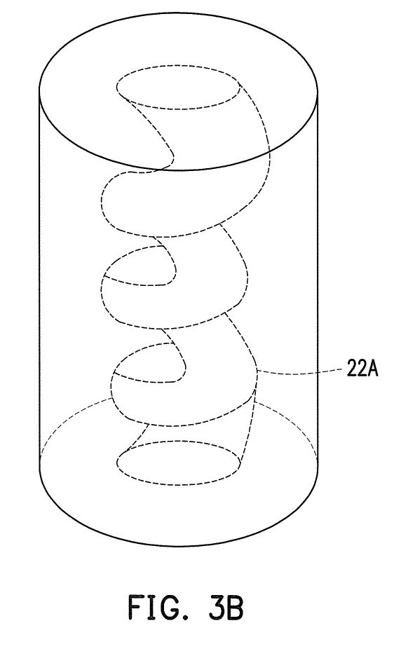

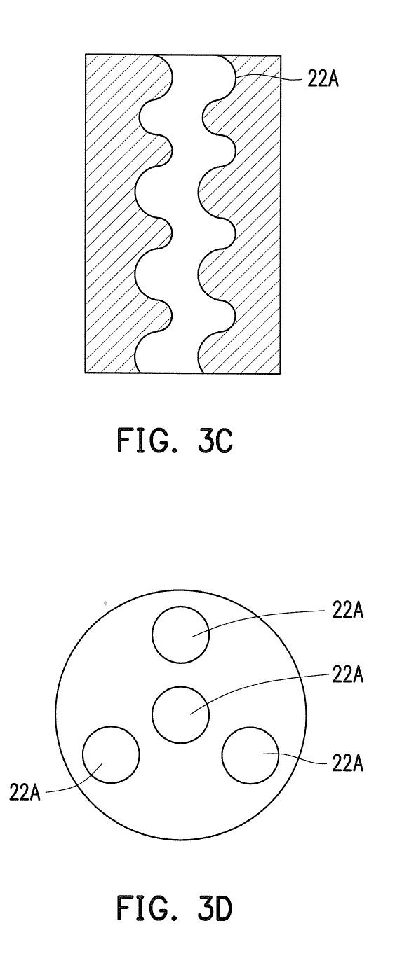

Please refer to FIG. 3A to FIG. 3D illustrating schematic diagrams of a nozzle of embodiments of the disclosure. As shown in the transparent perspective view of FIG. 3A, a nozzle 142A has at least one flow channel 22A therein, and the nozzle 142A has an entry portion 1421 and an exit portion 1422. The entry portion connects to the flow channel 22A and a fluid supply source (not illustrated). The exit portion 1422 connects to the flow channel 22A and is located at another end of the nozzle 142A relative to the entry portion 1421. The exit portion 1422 is closer than the entry portion 1421 is to the carrying device 130. In the embodiment of FIG. 3A, the exit portion 1422 of the nozzle 142A further has a vane 32A that is disposed to be rotatable at the exit portion 1422 and suitable for causing the disturbed fluid GA to be injected to the evaporation chamber 110 after passing through the flow channel 22A and the vane 32A.

FIG. 3B and FIG. 3C are schematic views of the flow channels in the nozzles of different embodiments. As shown in the transparent perspective view of FIG. 3B, the flow channel 22A can be a three-dimensional spiral channel, and as shown in the cross-sectional view of FIG. 3C, the flow channel 22A can be a curved channel.

In an embodiment, as shown in the top view of FIG. 3D, each of the nozzles 142A of the fluid disturbance device 140 has a plurality of flow channels 22A therein. Each of the flow channels 22A can also be the three-dimensional spiral channel of FIG. 3B or the curved channel of FIG. 3C.

The nozzle of the fluid disturbance device of the disclosure is designed to have a flow channel, such that after the fluid sequentially passes through the entry portion, the flow channel, and the exit portion, the fluid becomes the disturbed fluid entering into the evaporation space.

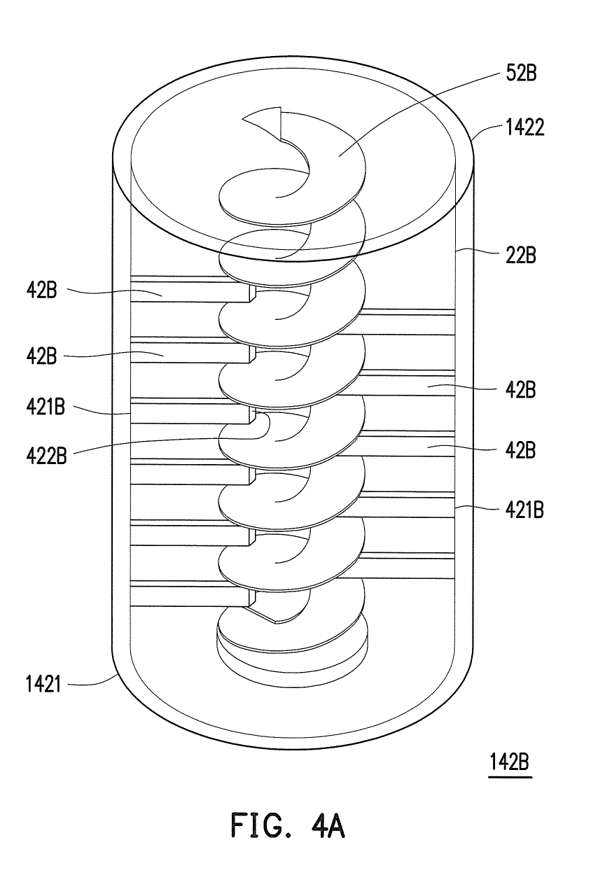

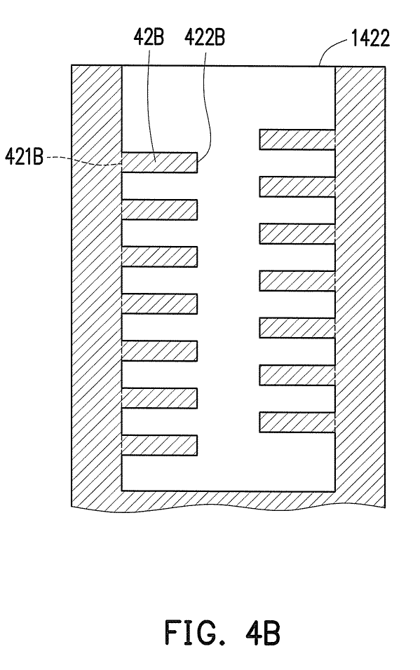

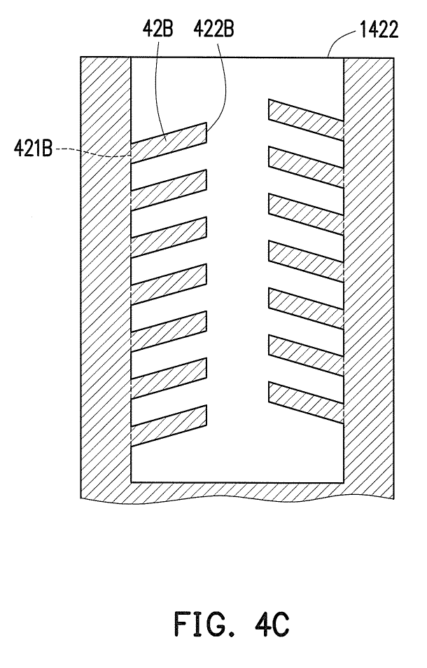

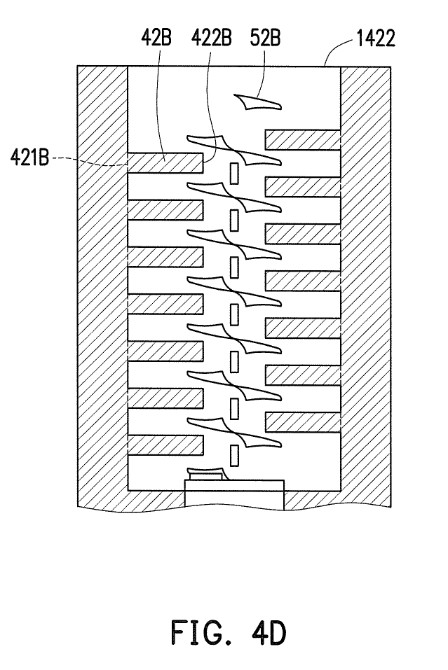

Please refer to FIG. 4A to 4D illustrating schematic diagrams of a nozzle of another embodiment of the disclosure. As shown in the transparent perspective view of FIG. 4A and as shown in FIG. 4B, a nozzle 142B has a flow channel 22B therein, and the nozzle 142B has an entry portion 1421 and an exit portion 1422. The entry portion connects to the flow channel 22B and a fluid supply source (not illustrated). The exit portion 1422 connects to the flow channel 22B and is located at another end of the nozzle 142B relative to the entry portion 1421. The exit portion 1422 is closer than the entry portion 1421 is to the carrying device 130. In this embodiment, the flow channel 22B includes a plurality of side-wall stoppers 42B. Each of the side-wall stoppers 42B has a connection portion 421B connected to an inner wall of the flow channel 22B. Each of the side-wall stoppers 42B also has an end portion 422B pointing the central axis of the flow channel 22B. In the embodiment of FIG. 4C, a distance between the end portion 422B of each side-wall stoppers and the exit portion 1422 is less than a distance between the connection portion 421B thereof and the exit portion 1422.

Please refer again to FIGS. 4A and 4D, the flow channel 22B further has a three-dimensional spiral stopper 52B. The plurality of side-wall stoppers 42B are positioned between the three-dimensional spiral stopper 52B and the inner wall of the flow channel 22B. As shown in FIG. 4D, the end portions 422B of the side-wall stoppers and the three-dimensional spiral stopper 52B are staggeredly disposed. The plurality of side-wall stoppers 42B and the three-dimensional spiral stopper 52B are suitable for causing the fluid to become the disturbed fluid entering into the evaporation space after passing through the flow channel 22B.

In another embodiment, a nozzle of the fluid disturbance device of the disclosure has at least one flow channel and has a rotation axis. When the fluid passes through the rotating flow channel, the fluid becomes the disturbed fluid entering into the evaporation space.

The disturbed fluid injected by the fluid disturbance device of the disclosure is a noble gas, an inert gas, or a gas not easily producing a reaction with the evaporation particles. In addition, the fluid disturbance device or the fluid can be heated. As another example, the temperature of the disturbed fluid injected into the evaporation space at least reaches the room temperature. In an embodiment, the fluid disturbance device has a fluid heating component (not illustrated) suitable for heating the disturbed fluid before injection into the evaporation space S. Furthermore, the fluid heating component can be a heating ring (not illustrated) sleeved on each of the nozzles.

A method of performing evaporation using the evaporation apparatus disclosed in the above embodiments is as follows. Firstly, an evaporation source is disposed at a lower part in the evaporation space, the evaporation source accommodating an evaporation source material; a carrying device is disposed, the carrying device being disposed to be rotatable about a reference axis as the center at an upper part in the evaporation space and being opposite to the evaporation source, the carrying device being configured for carrying an object awaiting deposition, such as a substrate and positioning the substrate between the evaporation source and the carrying device; a fluid disturbance device is disposed, suitable for injecting a disturbed fluid towards the carrying device in the evaporation space.

Although the present disclosure has been described with reference to the above embodiments, it will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An evaporation apparatus, comprising:
an evaporation chamber, having an evaporation space;
an evaporation source disposed at a lower part in the evaporation space, the evaporation source being suitable for accommodating an evaporation source material;
a carrying device being disposed to be rotatable about a reference axis as the center at an upper part in the evaporation space, and being opposite to the evaporation source, the carrying device being suitable for carrying a substrate and positioning the substrate between the evaporation source and the carrying device; and
a fluid disturbance device being suitable for injecting a disturbed fluid towards the carrying device in the evaporation space;
wherein the fluid disturbance device comprises a plurality of nozzles, the plurality of nozzles being disposed in a symmetrical arrangement with the reference axis as the center, and each of the plurality of nozzles being disposed to inject the disturbed fluid in an injecting direction, the injecting direction intersecting with the reference axis at an angle, such that the disturbed fluid travels towards the carrying device.

2. The evaporation apparatus according to claim 1, wherein the reference axis passes through a disposed position of the evaporation source, and the angle being between 0° to 15° and not equal to 0°.

3. The evaporation apparatus according to claim 1, wherein each of the plurality of nozzles has at least one flow channel.

4. The evaporation apparatus according to claim 3, wherein the at least one flow channel is a three-dimensional spiral channel.

5. The evaporation apparatus according to claim 3, wherein the at least one flow channel is a curved channel.

6. The evaporation apparatus according to claim 3, wherein the at least one flow channel comprises a plurality of side-wall stoppers, the plurality of side-wall stoppers each has a connection portion connected to an inner wall of the at least one flow channel and an end portion pointing in the injecting direction, and a distance between the end portion and the carrying device is less than a distance between the connection portion and the carrying device.

7. The evaporation apparatus according to claim 6, wherein the at least one flow channel further comprises a three-dimensional spiral stopper suitable, the plurality of side-wall stoppers is positioned between the three-dimensional spiral stopper and the inner wall.

8. The evaporation apparatus according to claim 3, wherein each of the plurality of nozzles has an entry portion and an exit portion, the entry portion is connected to the at least one flow channel and a fluid supply source, the exit portion is connected to the at least one flow channel and located at another end of the each of the plurality of nozzles relative to the entry portion, and the exit portion is closer than the entry portion is to the carrying device.

9. The evaporation apparatus according to claim 8, wherein each of the plurality of nozzles has a vane disposed to be rotatable at the exit portion.

10. The evaporation apparatus according to claim 1, wherein each of the plurality of nozzles has a rotation axis.

11. The evaporation apparatus according to claim 1, wherein the fluid disturbance device has a fluid heating component suitable for heating the disturbed fluid before injection into the evaporation space.

12. The evaporation apparatus according to claim 1, wherein the carrying device is suitable for rotating about the reference axis as the center, causing the substrate to be moved along an annular path.

13. A method of evaporation using the evaporation apparatus according to claim 1, the method of evaporation comprising:
disposing the evaporation source in the evaporation space of the evaporation chamber, and at the lower part in the evaporation space, the evaporation source being suitable for accommodating an evaporation source material;
disposing the carrying device, the carrying device being disposed to be rotatable about the reference axis as the center at the upper part in the evaporation space, and being opposite to the evaporation source, the carrying device being suitable for carrying a substrate and positioning the substrate between the evaporation source and the carrying device; and
disposing the fluid disturbance device, suitable for injecting the disturbed fluid towards the carrying device in the evaporation space;
wherein the fluid disturbance device comprises the plurality of nozzles, the plurality of nozzles is disposed in a symmetrical arrangement with the reference axis as the center, and each of the plurality of nozzles is disposed to inject the disturbed fluid in the injecting direction, the injecting direction intersecting with the reference axis at the angle, such that the disturbed fluid travels towards the carrying device.

14. The evaporation method according to claim 13, wherein the reference axis passes through the disposed position of the evaporation source, the angle being between 0° to 15° and not equal to 0°.

15. The evaporation method according to claim 13, wherein each of the plurality of nozzles has at least one flow channel.

16. The evaporation method according to claim 15, wherein the at least one flow channel comprises a plurality of side-wall stoppers, the plurality of side-wall stoppers each has a connection portion connected to an inner wall of the at least one flow channel and an end portion pointing in the injecting direction, and a distance between the end portion and the carrying device is less than a distance between the connection portion and the carrying device.

17. The evaporation method according to claim 16, wherein the at least one flow channel further comprises a three-dimensional spiral stopper suitable, the plurality of side-wall stoppers is positioned between the three-dimensional spiral stopper and the inner wall.

18. The evaporation method according to claim 15, wherein each of the plurality of nozzles has an entry portion and an exit portion, the entry portion is connected to the at least one flow channel and a fluid supply source, the exit portion is connected to the at least one flow channel and located at another end of the each of the plurality of nozzles relative to the entry portion, and the exit portion is closer than the entry portion is to the carrying device.

19. The evaporation method according to claim 18, wherein each of the plurality of nozzles has a vane disposed to be rotatable at the exit portion.

20. The evaporation method according to claim 13, wherein each of the plurality of nozzles has a rotation axis.

21. The evaporation method according to claim 13, wherein the carrying device is suitable for rotating about the reference axis as the center, causing the substrate to be moved along an annular path.

22. The evaporation method according to claim 13, wherein the evaporation source comprises a crucible, the crucible being configured for accommodating the evaporation source material, suitable for causing the evaporation source material to evaporate into evaporation particles to be deposited on the substrate.
